(19) United States
(12) Patent Application Publication
(10) Pub. No.: US 2015/0241771 A1
(43) Pub. Date: Aug. 27, 2015

(54) PHOTORESIST COMPOSITIONS AND METHODS OF FORMING PATTERNS USING THE SAME

(71) Applicant: SAMSUNG ELECTRONICS CO., LTD., Suwon-si (KR)

(72) Inventors: Suk-Koo HONG, Seongnam-si (KR); Jong-Chan LEE, Seoul (KR); Su-Jee KWON, Seoul (KR); Dong-Gyun KIM, Seoul (KR); Joon-Je LEE, Suwon-si (KR); Hyung-Rae LEE, Hwaseong-si (KR)

(73) Assignee: SNU R&DB FOUNDATION, Seoul (KR)

(21) Appl. No.: 14/625,954

(22) Filed: Feb. 19, 2015

(30) Foreign Application Priority Data
Feb. 26, 2014 (KR) 10-2014-0022280

(51) Int. Cl. G03F 7/038

(52) U.S. Cl. CPC G03F 7/038

(57) ABSTRACT

A photoresist composition includes a photosensitive copolymer having a repeating unit from a vinyl sulfone monomer, and a solvent.

### CROSS-REFERENCE TO RELATED APPLICATION

Korean Patent Application No. 10-2014-0022280, filed on Feb. 26, 2014 in the Korean Intellectual Property Office, and entitled: “Photoresist Compositions and Methods of Forming Patterns Using the Same,” is incorporated by reference herein in its entirety.

### BACKGROUND

1. Field

Example embodiments relate to photoresist compositions and methods of forming patterns using the same, for example, negative-type photoresist compositions and methods of forming patterns using the same.

2. Description of the Related Art

A photolithography process may be utilized for forming a pattern included in a semiconductor device. For example, a photoresist layer may be formed on an object layer using a photoresist composition, and the photoresist layer may be transformed into a photoresist pattern by exposure and developing processes. The object layer may be partially etched using the photoresist pattern as an etching mask to form the pattern of the semiconductor device.

### SUMMARY

Embodiments may be realized by providing a photoresist composition, including a photosensitive copolymer including a repeating unit from a vinyl sulfone monomer; and a solvent.

The photosensitive copolymer may be represented by Chemical Formula 1:

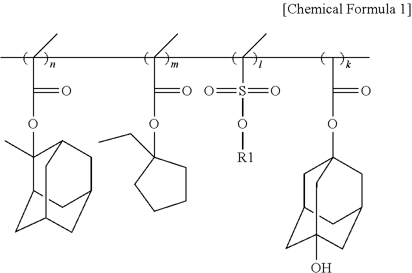

wherein, in Chemical Formula 1, R1 is a hydrocarbon group, and n, m, l and k are positive integers.

The photosensitive copolymer may be represented by Chemical Formula 2:

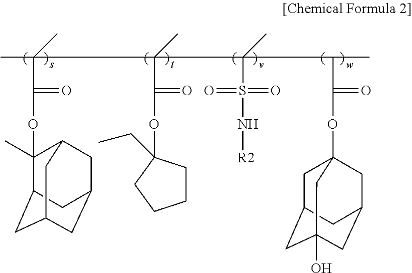

wherein, in Chemical Formula 2, R2 is a hydrocarbon group, and s, t, v and w are positive integers.

An amount of the photosensitive copolymer may range from about 1 weight percent to about 60 weight percent, based on a total weight of the photoresist composition.

The photoresist composition may further include a photoacid generator and a basic additive.

An amount of the photoacid generator may range from about 1 weight percent to about 20 weight percent, based on a total weight of the photoresist composition.

An amount of the basic additive may range from about 0.001 weight percent to about 5 weight percent, based on a total weight of the photoresist composition.

Embodiments may be realized by providing a method of forming a pattern, including forming a photoresist layer from a photoresist composition including a photosensitive copolymer and a solvent on an object layer, the photosensitive copolymer including a repeating unit from a vinyl sulfone monomer; forming a photoresist pattern, forming the photoresist pattern including performing a light exposure on the photoresist layer; and etching the object layer using the photoresist pattern as an etching mask.

The photoresist composition may further include a photoacid generator and a basic additive.

The photosensitive copolymer may be represented by Chemical Formula 1 or Chemical Formula 2:

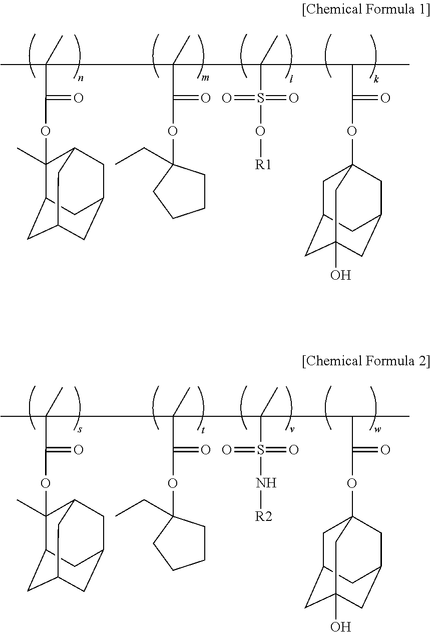

wherein, in Chemical Formula 1 and Chemical Formula 2, R1 and R2 are independently a hydrocarbon group, and n, m, l, k, s, t, v and w are positive integers.

An amount of the photosensitive copolymer may range from about 1 weight percent to about 60 weight percent, based on a total weight of the photoresist composition.

The forming of the photoresist pattern may include partially exposing the photoresist layer to light using an exposure mask; performing a thermal treatment on the photoresist layer; and developing the photoresist layer using an organic solvent.

The thermal treatment may be performed at a temperature ranging from about 90° C. to about 130° C.

The method may further include, before forming the photoresist layer, forming a hard mask layer on the object layer.

The etching of the object layer may include etching the hard mask layer using the photoresist pattern as an etching mask to form a hard mask; removing the photoresist pattern; and etching the object layer using the hard mask as an etching mask.

Embodiments may be realized by providing a photoresist composition, including a photosensitive copolymer including a sulfone group; and a solvent.

The sulfone group may be represented by either of the following Chemical Formula 3 and Chemical Formula 4:

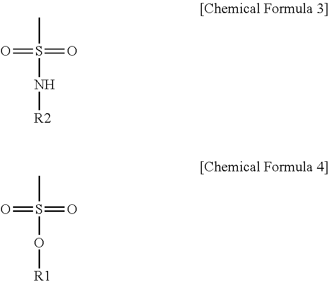

wherein R1 and R2 are independently a hydrocarbon group.

The photosensitive copolymer may include a plurality of the sulfone group represented by Chemical Formula 3 or Chemical Formula 4.

The photosensitive copolymer may further include one or more of the following chemical groups:

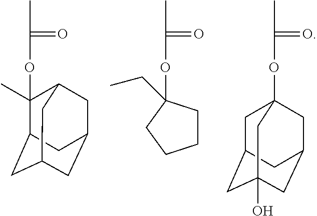

The photosensitive copolymer may include all the following chemical groups:

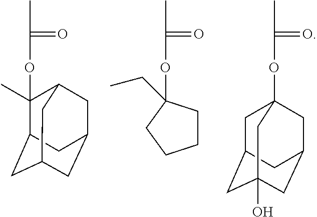

### BRIEF DESCRIPTION OF THE DRAWINGS

Features will become apparent to those of skill in the art by describing in detail exemplary embodiments with reference to the attached drawings in which:

FIGS. 1 to 4 illustrate cross-sectional views of a method of forming a pattern in accordance with example embodiments; and

FIGS. 5 to 29 illustrate top plan views and cross-sectional views of a method of manufacturing a semiconductor device in accordance with example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to be limiting.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a transistor structure) is illustrated in a cross-sectional view, an electronic device may include a plurality of the device structures (e.g., transistor structures), as would be illustrated by a plan view of the electronic device. The plurality of device structures may be arranged in an array and/or in a two-dimensional pattern.

Unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Photoresist Compositions

A photoresist composition may include a photosensitive copolymer, and may additionally include a photoacid generator (PAG), a basic additive and a solvent. In example embodiments, the photosensitive copolymer may include a repeating unit from a vinyl sulfone monomer, and the photosensitive copolymer may have improved adhesion and hydrophilicity. Further, the repeating unit from the vinyl sulfone monomer may be capable of forming hydrogen bonds. A negative-type photoresist layer that may have improved adhesion and etching resistance may be formed using the photoresist composition.

For example, the photosensitive copolymer having the repeating unit from a vinyl sulfone monomer may be represented by at least one of the following Chemical Formulae 1 and 2.

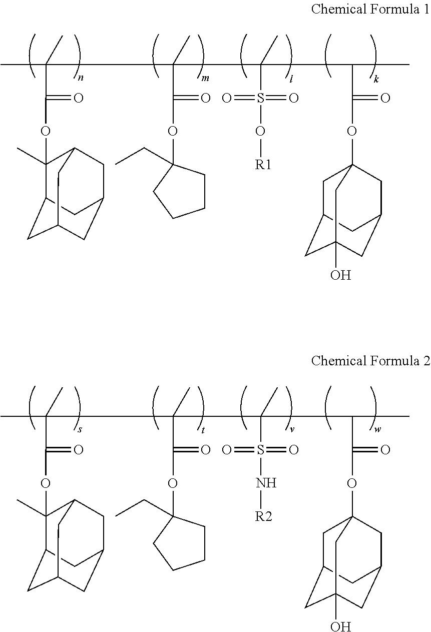

In Chemical Formulae 1 and 2, R1 and R2 may each independently be a hydrocarbon group, and n, m, l, k, s, t, v and w are positive integers. For example, R1 and R2 may each be C₁-C₂₀ alkyl group. For example, each of n, m, l, k, s, t, v and w is a positive integer from 2 to 10,000.

Examples of R1 and R2 include groups represented by the following Chemical Formulae 3 to 9:

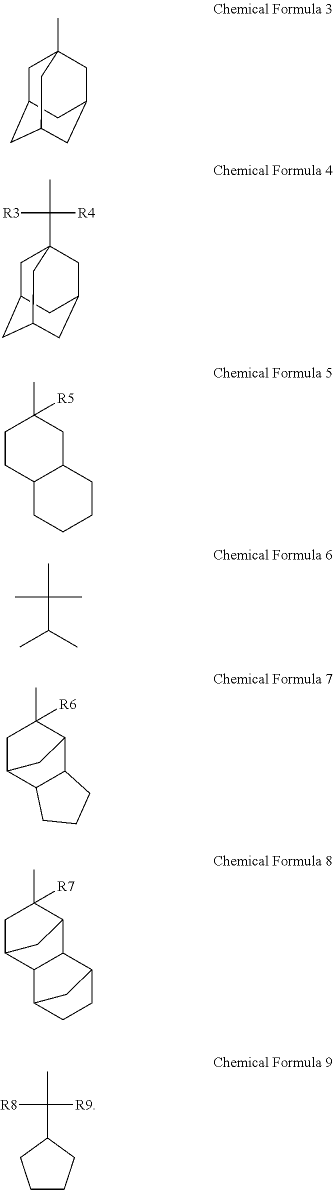

In Chemical Formulae 3 to 9, R3, R4, R5, R6, R7, R8 and R9 may each independently be a C₁-C₄ alkyl group.

In example embodiments, an amount of the photosensitive copolymer in the photoresist composition may range from about 1 weight percent (wt %) to about 60 weight percent, based on a total weight of the photoresist composition. Maintaining the amount of the photosensitive copolymer within this range may help form a photoresist layer or a photoresist pattern with a uniform thickness. The amount of the photosensitive copolymer may be adjusted in consideration of a viscosity and/or a coat-ability of the photoresist composition.

Adding a photoacid generator to the photoresist composition may help facilitate adhesion of the photoresist composition. Exemplary photoacid generators include an onium salt such as triphenylsulfonium trifluoromethanesulfonate, an aromatic diazonium salt, a sulfonium salt, a triarylsulfonium salt, a diarylsulfonium salt, a monoarylsulfonium salt, an iodonium salt, a diaryliodonium salt, nitrobenzyl ester, disulfone, diazo-disulfone, sulfonate, trichloromethyl trizine, N-hydroxysuccinimide triflate, or combinations thereof.

In example embodiments, an amount of the photoacid generator in the photoresist composition may range from about 1 wt % to about 20 wt %, based on the total weight of the photoresist composition. Maintaining the amount of the photoacid generator within this range may help preservce a sensitivity of the photoresist layer to light exposure, and avoid an undercut of the photoresist pattern, for example, due to excessive light absorption. In one example embodiment, the amount of the photoacid generator may range from about 1 wt % to about 10 wt %, based on the total weight of the photoresist composition.

Adding a basic additive to the photoresist composition may help control an amount of acid therein. In example embodiments, an amount of the basic additive may range from about 0.001 wt % to about 5 wt %. Maintaining the amount of the basic additive within this range may help avoid an undercut of the photoresist pattern, and preserve a resolution and a sensitivity of the photoresist composition.

The basic additive may include an organic compound containing a nitrogen atom, e.g., a nitrogen-containing base, e.g., triethylamine (TEA), trioctylamine (TOA), triisobutylamine, triisooctylamine, diethanolamine, triethanolamine, 2-piperidine ethanol, or combinations thereof.

An organic solvent that may be capable of solubilizing the photosensitive copolymer, the photoacid generator and the basic additive may be used. Exemplary solvents include propylene glycol monomethyl ether acetate (PGMEA), propylene glycole, ethylene glycol monoethyl ether, ethylene glycol monomethyl ether, diethylene glycol monoethyl ether, toluene, xylene, methylmethoxypropionate, N,N-dimethylforamide, N,N-dimethylacetamide, methylethylketone, or combinations thereof.

In one example embodiment, the photoresist composition may further include a surfactant, a cross-linking agent, a thermal acid generator, a filler and/or a viscosity modifier.

The surfactant may include a non-ionic surfactant, a cationic surfactant, an anionic surfactant and/or an amphoteric surfactant. Adding a cross-linking agent to the photoresist composition may help facilitate a cross-linking of the photosensitive copolymer. The cross-linking agent may include, e.g., a melamine resin and/or a urea resin. The filler may include, e.g., barium sulfate and/or talc. The viscosity modifier may include, e.g., silica.

Preparations of Photoresist Compositions

For example, a vinyl sulfone monomer may be synthesized by reacting a hydrocarbon compound that may have a hydroxyl group (R—OH) or a hydrocarbon compound that may have an amino group (R—NH₂) with sulfonyl dicholride (SO₂Cl₂). The vinyl sulfone monomer may be polymerized to form a photosensitive copolymer. The photoresist copolymer may be mixed with a photoacid generator, a basic additive and a solvent to form a photoresist composition.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

A hydrocarbon compound represented by Chemical Formula 10 and SO₂Cl₂ were dissolved in dichloromethane (CH₂Cl₂) to form a mixture. TEA was added to the mixture and stirred at 0° C. for about 30 minutes to about 3 hours to form a monomer represented by Chemical Formula 11. The monomer was dissolved in tetrahyrdofuran (THF) together with a monomer represented by Chemical Formula 12, a monomer represented by Chemical Formula 13 and a monomer represented by Chemical Formula 14. Azobisisobutyronitrile (AIBN) was added into the resultant mixture above, and heated and stirred for about 1 hour to form a photosensitive copolymer represented by Chemical Formula 15. The photosensitive copolymer was dissolved in PGMEA together with triphenylsulfonium trifluoromethanesulfonate and TOA, and filtered to achieve a photosensitive composition.

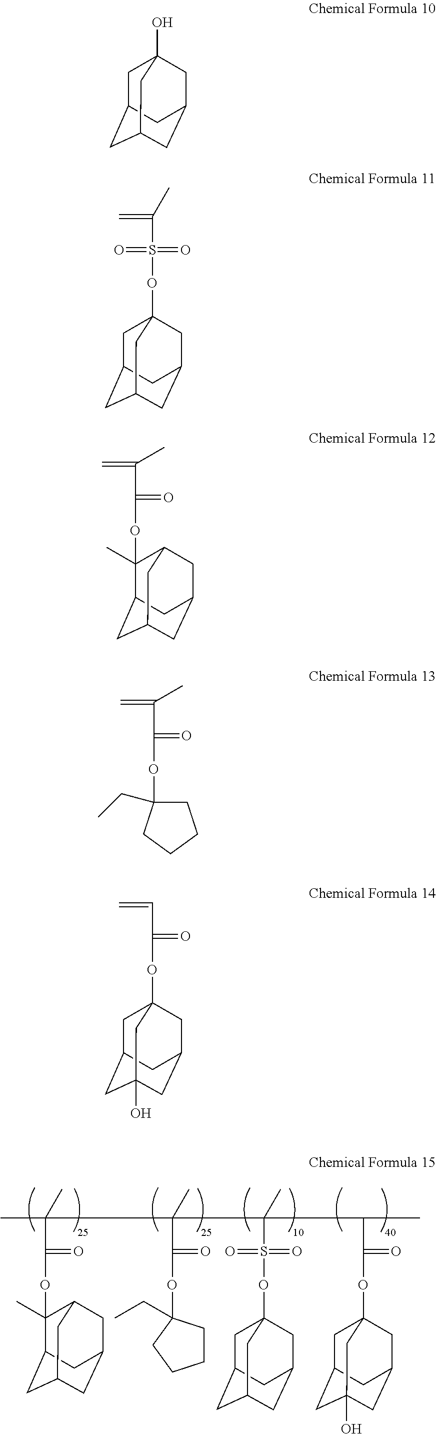

### Example 2

A hydrocarbon compound represented by Chemical Formula 16 and SO₂Cl₂ were dissolved in CH₂Cl₂ to form a mixture. TEA was added to the mixture and stirred at 0° C. for about 30 minutes to about 3 hours to form a monomer represented by Chemical Formula 17. The monomer was dissolved in THF together with the monomer represented by Chemical Formula 12, the monomer represented by Chemical Formula 13 and the monomer represented by Chemical Formula 14. AIBN was added into the resultant mixture above, and heated and stirred for about 1 hour to form a photosensitive copolymer represented by Chemical Formula 18. The photosensitive copolymer was dissolved in PGMEA together with triphenylsulfonium trifluoromethanesulfonate and TOA, and filtered to achieve a photosensitive composition.

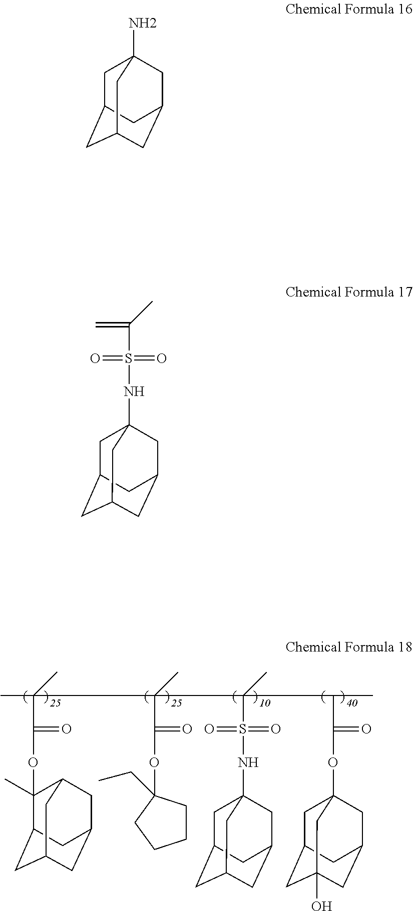

Methods of Forming Patterns

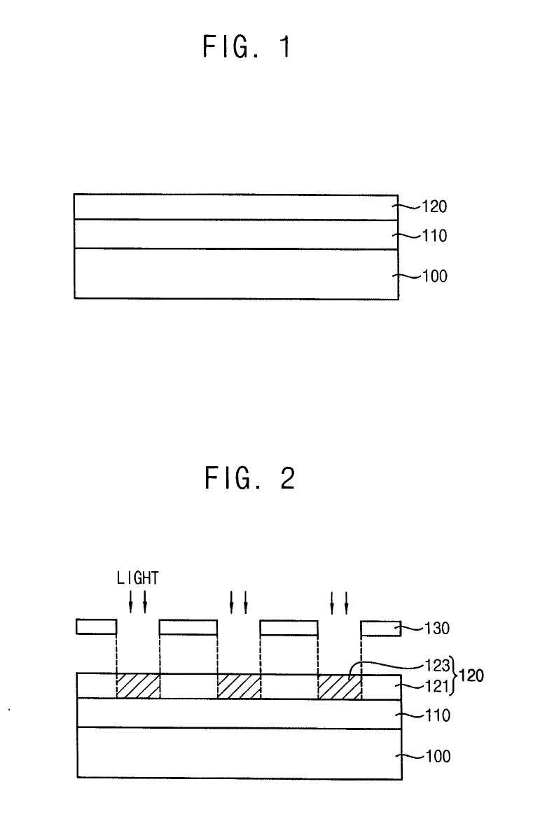

FIGS. 1 to 4 illustrate cross-sectional views of a method of forming a pattern in accordance with example embodiments. For example, the photoresist composition as described above may be utilized for formation of the pattern.

Referring to FIG. 1, a hard mask layer 110 and a photoresist layer 120 may be sequentially formed on an object layer 100. The photoresist layer 120 may be formed using the photoresist composition in accordance with example embodiments.

In example embodiments, the photoresist composition may be coated on the object layer 100 by, e.g., a spin coating process, a spray coating process or a dip coating process, and then a soft-baking process may be performed to form the photoresist layer 120. A solvent may be evaporated from the photoresist composition during the soft-baking process. The photoresist layer 120 may include a photosensitive copolymer having a repeating unit from a vinyl sulfone monomer, a photoacid generator and a basic additive. The photoacid copolymer generated from the vinyl sulfone monomer may have improved adhesion and hydrophilicity, and the photoresist layer 120 may also have improved adhesion with respect to the hard mask layer 110.

The hard mask layer 110 may include a material that may have a different etching selectivity with respect to the object layer 100 and the photoresist layer 120. For example, the hard mask layer 110 may be formed using a carbon-based spin on hard mask (SOH) material. The hard mask layer 110 may have a multi-layered structure.

Referring to FIG. 2, the photoresist layer 120 may be exposed to light using an exposure mask 130. The photoresist layer 120 may be divided into an exposed portion 123 that may be cured by a light exposure and a non-exposed portion 121.

An acid may be generated in the exposed portion 123 by the photoacid generator, and the acid may be diffused or transferred to an interface between the exposed portion 123 and the hard mask layer 110.

A thermal treatment may be further performed on the photoresist layer 120 to improve adhesion of the photoresist layer 120. In one example embodiment, the thermal treatment may be performed at a temperature ranging from about 90° C. to about 130° C. for, e.g., about 50 seconds to about 200 seconds.

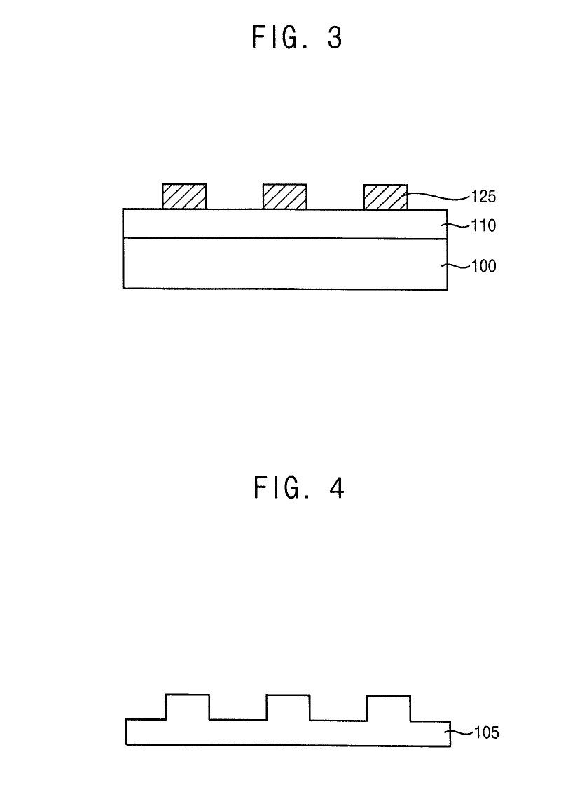

Referring to FIG. 3, a developing process may be performed on the photoresist layer 120 using an organic solvent. The non-exposed portion 121 may be dissolved and removed by the organic solvent. The exposed portion 123 may remain on the hard mask layer 110 such that a photoresist pattern 125 may be defined.

Exemplary organic solvents include a ketone-based solvent, an ester-based solvent, an alcohol-based solvent, an amide-based solvent and an ether-based solvent.

The acid generated during the light exposure process may facilitate formation of a uniform sidewall profile of the photoresist pattern 125. The sidewall of the photoresist pattern 125 may be substantially vertical with respect to a top surface of the hard mask layer 110. As described above, the photoresist layer 125 may have the improved adhesion to the hard mask layer 110, and the photoresist pattern 125 may not be detached or separated from the hard mask layer 110. Therefore, a resolution and a sensitivity of the photoresist composition may be also improved.

Referring to FIG. 4, the hard mask layer 110 may be etched using the photoresist pattern as an etching mask. A hard mask pattern (not illustrated) may be formed on the object layer 100. The photoresist pattern 125 may be removed by an ashing process and/or a strip process after formation of the hard mask pattern.

Subsequently, the object layer 100 may be partially etched using the hard mask pattern as an etching mask to form a predetermined pattern.

As described above, the photoresist pattern 125 that may have improved resolution may be formed using the photoresist composition according to example embodiments. A desired pattern that may have, e.g., a high aspect ratio, a fine pitch and a high resolution may be obtained using the photoresist pattern 125 as an etching mask.

Methods of Manufacturing Semiconductor Devices

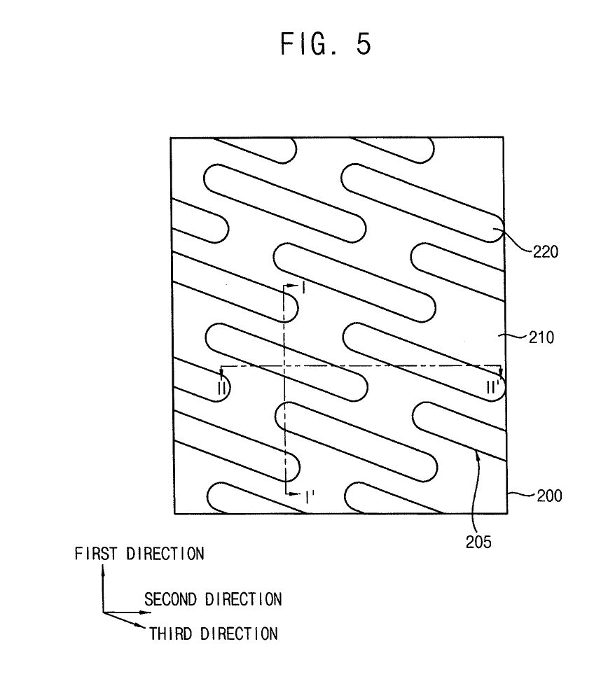

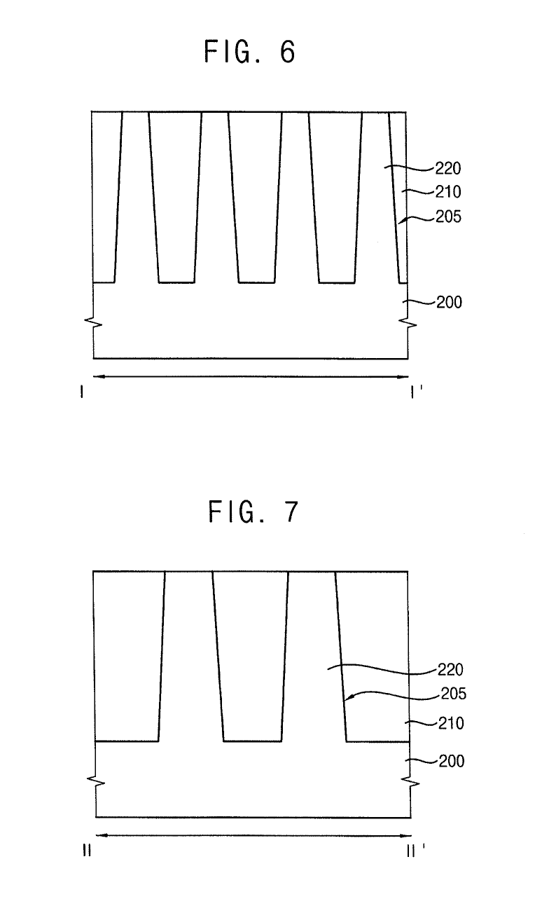

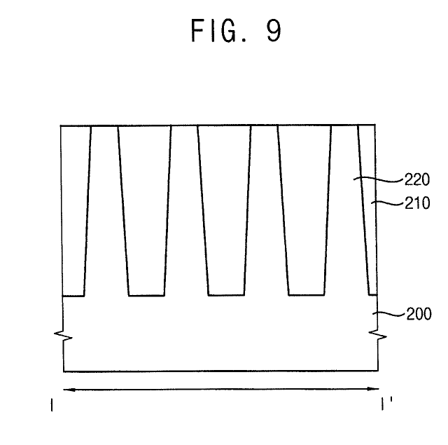

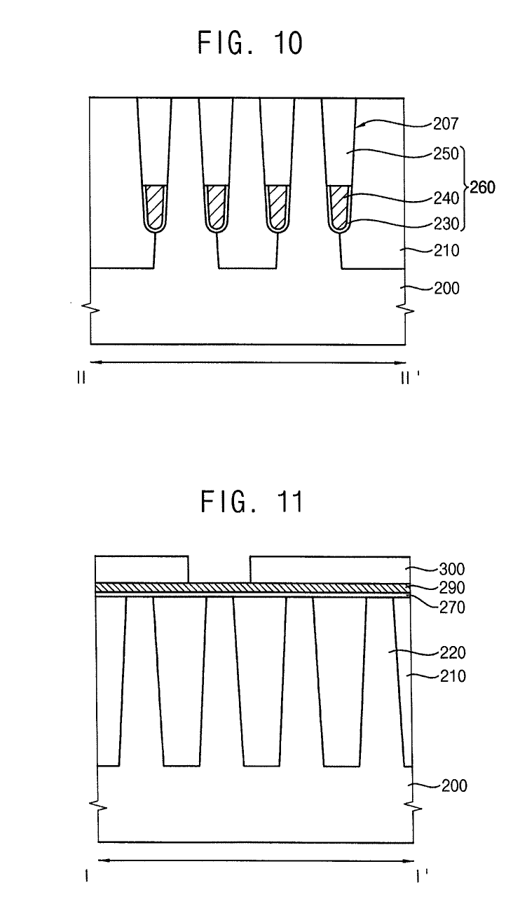

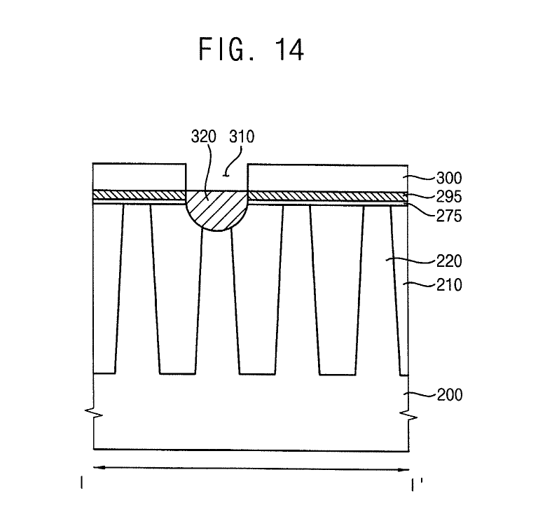

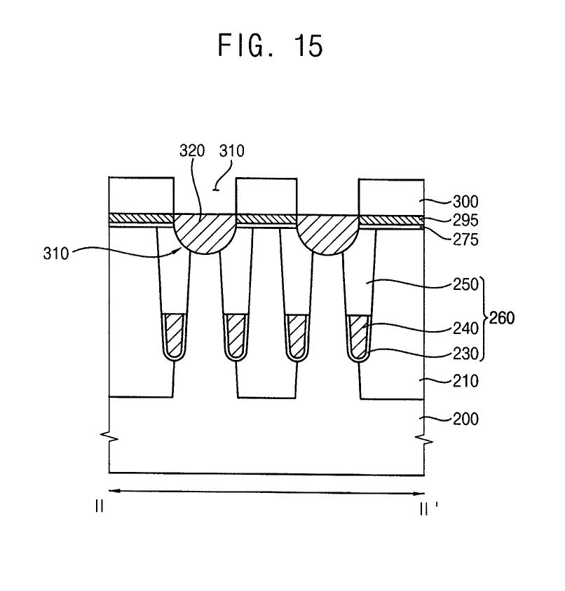

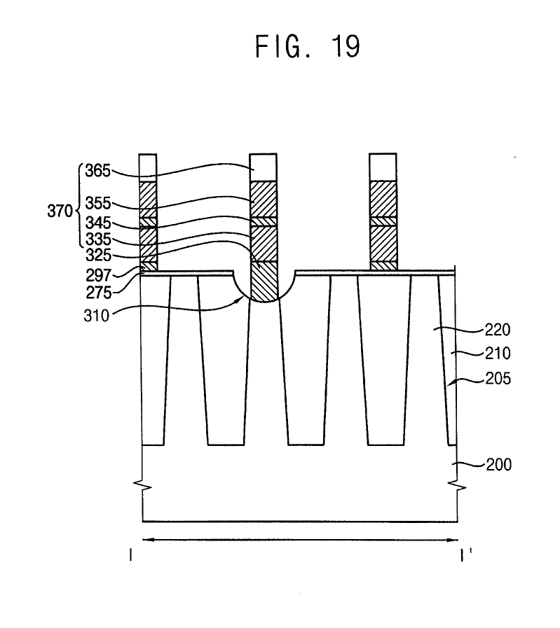

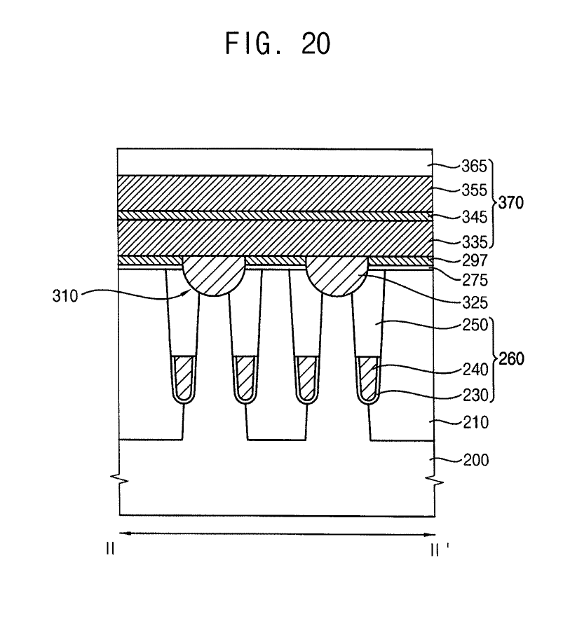

FIGS. 5 to 29 illustrate top plan views and cross-sectional views of a method of manufacturing a semiconductor device in accordance with example embodiments. FIGS. 5, 8, 13 and 18 illustrate top plan views of the method of manufacturing a semiconductor device. FIGS. 6, 9, 11, 14, 16, 19 and 21 to 28 are cross-sectional views taken along a line I-I′. FIGS. 7, 10, 12, 15, 17, 20 and 29 are cross-sectional views taken along a line II-II′.

In FIGS. 5 to 29, two directions parallel to a top surface of a substrate and substantially perpendicular to each other are referred to as a first direction and a second direction. The lines I-I′ and II-II′ are parallel to the first direction and the second direction, respectively. A direction parallel to the top surface of the substrate and crossing the first direction or the second direction by a predetermined angle is referred to as a third direction.

Referring to FIGS. 5 to 7, a first trench 205 may be formed at an upper portion of a substrate 200 by performing processes substantially the same as or similar to those illustrated with reference to FIGS. 1 to 4.

For example, a first mask layer (not illustrated) and a photoresist layer (not illustrated) may be formed sequentially on the substrate 200. The photoresist layer may be exposed to light and developed to form a photoresist pattern (not illustrated) by which a top surface of the first mask layer is partially exposed. The first mask layer may be partially etched using the photoresist pattern as an etching mask to form a first mask (not illustrated) by which a top surface of the substrate 200 is partially exposed. The photoresist pattern may be removed by an ashing process and/or a strip process. The upper portion of the substrate 200 may be partially removed using the first mask as the etching mask to form a first trench.

The photoresist layer may be formed using the photoresist composition according to example embodiments. Accordingly, the photoresist pattern may have improved adhesion and a high resolution, and the first trench 205 may be easily formed as a desired structure.

The first mask layer may include a material that may have a different etching selectivity form those of the substrate 200 and the photoresist layer. For example, the first mask layer may be formed using a carbon-based SOH material.

The substrate 200 may include, e.g., a single crystalline silicon substrate, a single crystalline germanium substrate, a silicon-germanium substrate, a silicon-on-insulator (SOI) substrate, or a germanium-on-insulator (GOI) substrate.

In one example embodiment, the first mask layer and the first mask may not be formed, and the photoresist pattern may be solely used as an etching mask.

An isolation layer pattern 210 may be formed in the first trench 205. For example, an isolation layer sufficiently filling the first trench 205 may be formed on the substrate 200. An upper portion of the isolation layer may be planarized until the top surface of the substrate 200 is exposed to form the isolation layer pattern 210. The first mask may be also removed by the planarization process. The isolation layer may be formed using an oxide, e.g., silicon oxide.

A portion of the substrate 200 covered by the isolation layer pattern 210 may be defined as a field region, and a portion of the substrate 200 not covered by the isolation layer pattern 210 may be defined as an active region 220. In example embodiments, a plurality of the active region 220 may be formed to be spaced apart from each other. Each active region 200 may extend in the third direction.

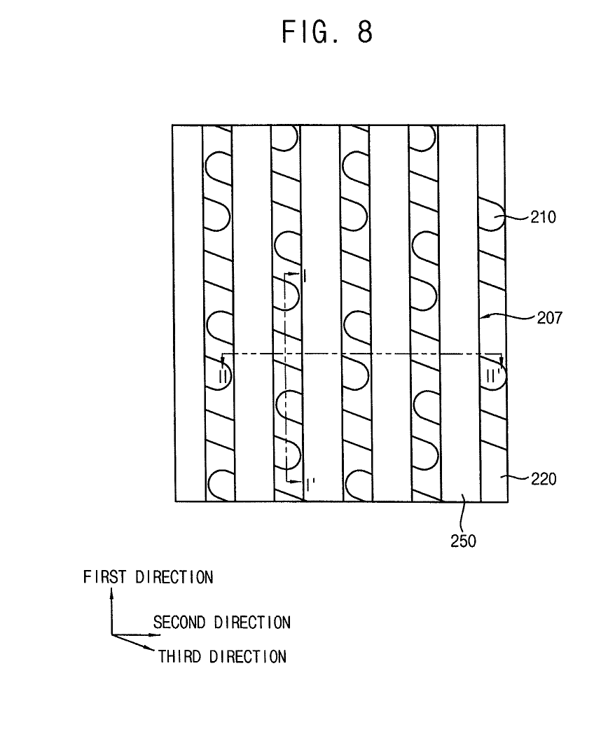

Referring to FIGS. 8 to 10, an impurity region (not illustrated) may be formed at an upper portion of the active region 220 by an ion-implantation process. The impurity region may include n-type impurities such as phosphorous (P) or arsenic (As), or p-type impurities such as boron (B).

Upper portions of the active region 220 and the isolation layer pattern 210 may be partially etched to form a second trench 207, and a gate structure 260 may be formed in the second trench 207.

In example embodiments, a photoresist pattern (not illustrated) may be formed on the active region 220 and the isolation layer pattern 210 using the photoresist composition described above. The active region 220 and the isolation layer pattern 210 may be partially removed using the photoresist pattern as an etching mask to form the second trench 207. The photoresist pattern may have improved adhesion and a high resolution, and the second trench 207 may be easily formed as a desired structure. For example, the second trench 207 may extend in the first direction, and a plurality of the second trenches 207 may be formed along the second direction.

A gate insulation layer 230 may be formed at a lower inner wall of the second trench 207, and a gate electrode 240 filling a lower portion of the second trench 207 may be formed on the gate insulation layer 230. A capping layer pattern 250 filling a remaining portion of the second trench 207 may be formed on the gate insulation layer 230 and the gate electrode 240. The gate structure 260 including the gate insulation layer 230, the gate electrode 240 and the capping layer pattern 250 may be formed in each second trench 207.

The gate structure 260 may be buried at the upper portion of the active region 220 and may extend in the first direction. A plurality of the gate structures 260 may be formed along the second direction. In example embodiments, two gate structures 260 may be formed in each active region 220.

The gate insulation layer 230 may be formed by a thermal oxidation process or a chemical vapor deposition (CVD) process. The gate isolation layer 230 may include an oxide, e.g., silicon oxide.

A gate electrode layer sufficiently filling the second trench 207 may be formed on the gate insulation layer 230, the isolation layer pattern 210 and the active region 220. An upper portion of the gate electrode layer may be planarized by a chemical mechanical polish (CMP) process and/or an etch-back process to form the gate electrode 240. An upper portion of the gate insulation layer 230 may be also removed by, e.g., the etch-back process. The gate insulation layer 230 may be formed on the lower inner wall of the second trench 207 to surround a sidewall and a bottom of the gate electrode 240. The gate electrode layer may be formed using a metal or a metal nitride such as, e.g., tungsten, titanium, tantalum, tungsten nitride, titanium nitride, or tantalum nitride.

A capping layer sufficiently filling a remaining portion of the second trench 207 may be formed on the gate insulation layer 230, the gate electrode 240, the isolation layer pattern 210 and the active region 220. An upper portion of the capping layer may be planarized until a top surface of the isolation layer pattern 210 is exposed to form the capping layer pattern 250. The capping layer may be formed using a nitride, e.g., silicon nitride.

A transistor may be defined by the impurity region and the gate structure 260, and the impurity region may serve as source and drain regions of the transistor.

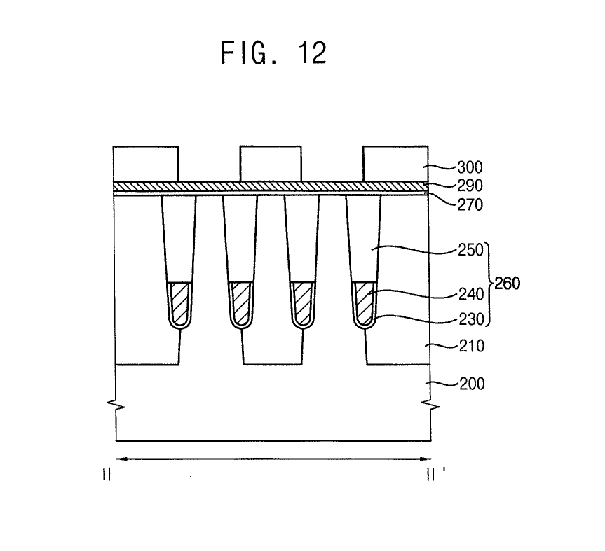

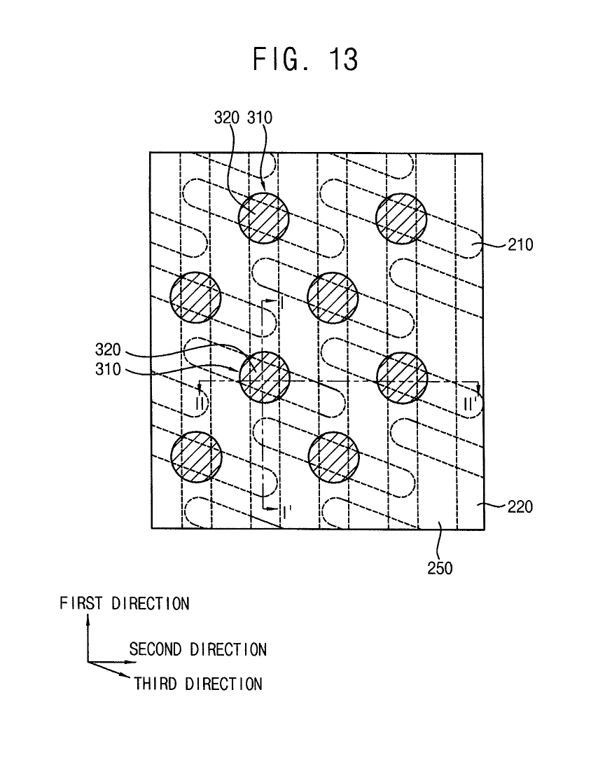

Referring to FIGS. 11 and 12, a pad layer 270, a first conductive layer 290 and a second mask 300 may be sequentially formed on the active region 220, the isolation layer pattern 210 and the capping layer pattern 250. A portion of the first conductive layer 290 superimposed over the active region 220 may be exposed by the second mask 300.

The first conductive layer 290 may be formed using, e.g. doped polysilicon. The first conductive layer 290 may have a first thickness of, e.g., about 60 Å.

The pad layer 270 may be formed using, e.g., an oxide such as silicon oxide.

Referring to FIGS. 13 to 15, the first conductive layer 290, the pad layer 270 and an upper portion of the active region 220 may be partially etched using the second mask 300 as an etching mask to form a recess 310. A second conductive layer pattern 320 may be formed in the recess 310. The first conductive layer 290 and the pad layer 270 may be changed into a first conductive layer pattern 295 and the pad layer pattern 275.

In example embodiments, a plurality of the recesses 310 may be formed along the first and second directions. During formation of the recess, portions of the capping layer pattern 250 and the isolation layer pattern 210 adjacent to the upper portion of the active region 220 may be also removed.

For example, a second conductive layer sufficiently filling the recess 310 may be formed on the active region 220, the isolation layer pattern 210, the capping layer pattern 250 and the second mask 300. An upper portion of the second conductive layer may be planarized by a CMP process and/or an etch-back process to form the second conductive layer pattern 320. Accordingly, a top surface of the second conductive layer pattern 320 may be coplanar with a top surface of the first conductive layer pattern 295. A plurality of the second conductive layer patterns 320 may be formed along the first and second directions. The second conductive layer may be formed using, e.g., doped polysilicon.

The second mask 300 may be removed by, e.g., an ashing process. After the removal of the second mask 300, a cleaning process such as a plasma native-oxide cleaning (PNC) process may be further performed on the substrate 200, and formation of a native oxide layer on the first and second conductive layer patterns 295 and 320 may be avoided.

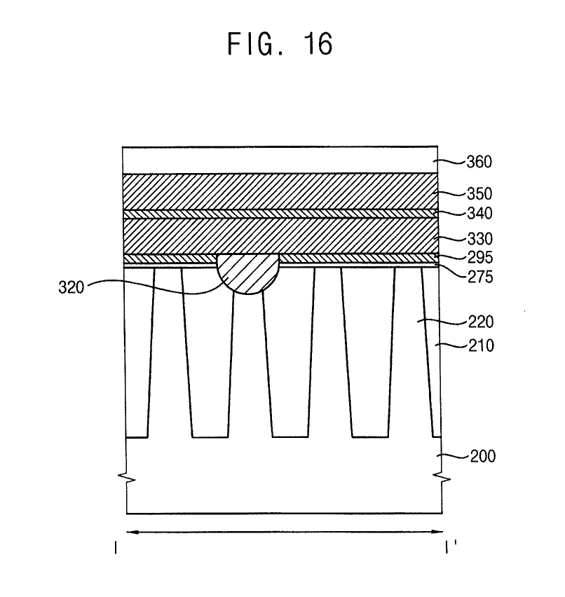

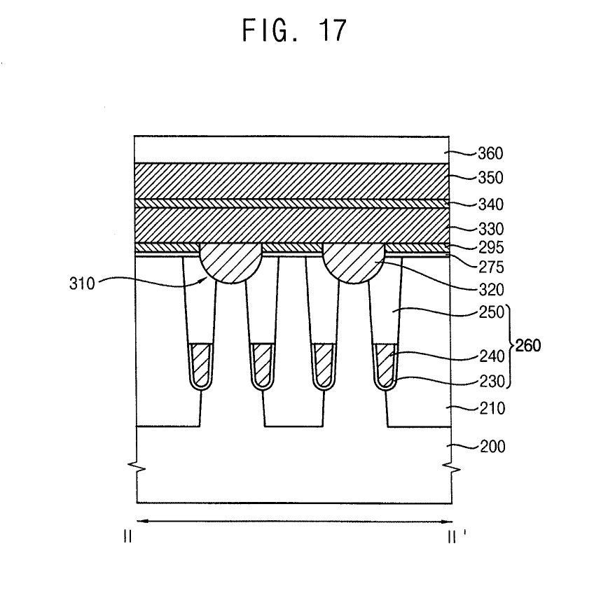

Referring to FIGS. 16 and 17, a third conductive layer 330, a barrier layer 340, a metal layer 350 and a third mask layer 360 may be sequentially formed on the first and second conductive layer patterns 295 and 320.

The third conductive layer 330 may be formed using a material substantially the same as or similar to those of the first and second conductive layer patterns 295 and 320. In this case, the third conductive layer 330 may be merged or integral with the first and second conductive layer patterns 295 and 320. The third conductive layer 330 may have a second thickness greater than the first thickness. For example, the third conductive layer 330 may have the second thickness of about 300 Å.

The barrier layer 340 may be formed using a metal nitride, e.g., tungsten nitride, titanium nitride, or tantalum nitride.

The metal layer 350 may be formed using a metal that may have a low resistance, e.g., tungsten.

The third mask layer 360 may be formed using silicon nitride.

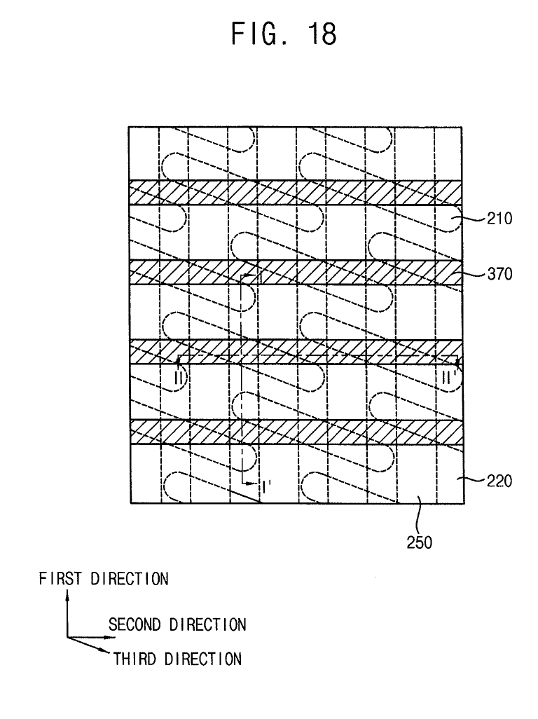

Referring to FIGS. 18 to 20, the third mask layer 360 may be partially etched to form a third mask 365. The metal layer 350, the barrier layer 340, the third conductive layer 330, and the first and second conductive layer patterns 295 and 320 may be sequentially etched using the third mask 365 as an etching mask. Accordingly, a bit line structure 370 including a third conductive layer pattern 335, a barrier layer pattern 345, a metal layer pattern 355 and the third mask 365 may be formed. A bit line contact 325 may be formed under the bit line structure 370. A top surface of the pad layer pattern 275 and an inner wall of the recess 310 may be partially exposed by the etching process.

The bit line contact 325 may be formed on a bottom of the recess 310 to be in contact with an upper surface of the active region 220. The bit line contact 325 may partially fill a recess 310, and a plurality of the bit line contacts 325 may be formed along the first and second directions.

The bit line structure 370 may be formed on the bit line contact 325. The bit line structure 370 may extend in the second direction, and a plurality of the bit line structures 370 may be formed along the first direction.

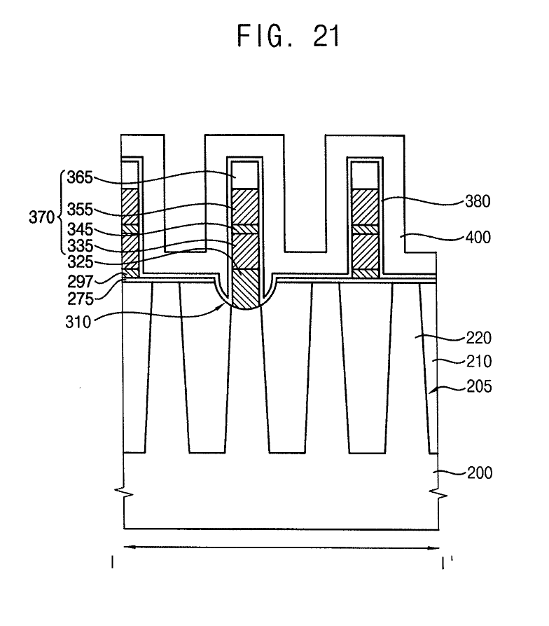

Referring to FIG. 21, a first spacer layer 380 and a first sacrificial layer 400 may be sequentially formed on the substrate 200 to cover the bit line contact 325 and the bit line structure 370.

The first spacer layer 380 may be formed by a CVD process, an atomic layer deposition (ALD) process and/or a plasma nitridation. The first spacer layer 380 may include a nitride, e.g., silicon nitride. In example embodiments, the first spacer layer 380 may be formed directly on the bit line contact 325 and the bit line structure 370, and may be formed conformably to have a uniform thickness.

The first sacrificial layer 400 may be formed by a CVD process or an ALD process using a material that may have an etching selectivity with respect to the first spacer layer 380. For example, the first sacrificial layer 400 may be formed using a silicon oxide-based material such as, e.g., boro-phospho-silicate glass (BPSG), Tonen Silazene (TOSZ), undoped silicate glass (USG), spin on glass (SOG), flowable oxide (FOX), tetra-ethyl-ortho-silicate (TEOS), or high density plasma-chemical vapor deposition (HDP-CVD) oxide.

The first sacrificial layer 400 may have a thickness greater than that of the first spaceer layer 380 to fill a remaining portion of the first recess 310.

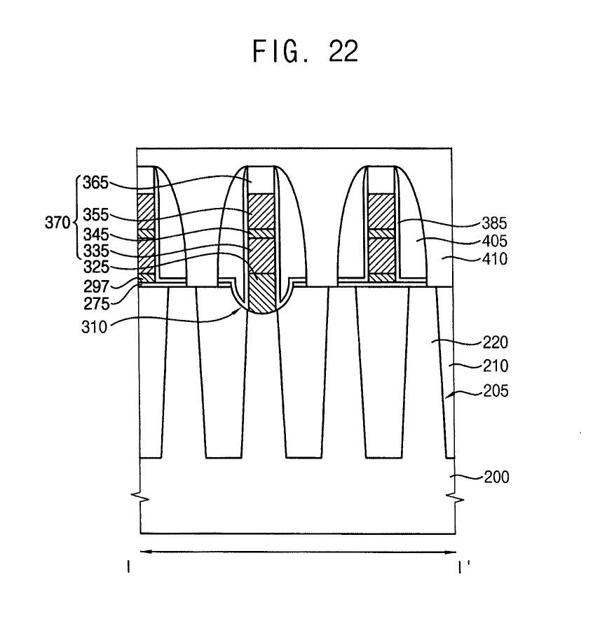

Referring to FIG. 22, the first sacrificial layer 400 and the first spacer layer 380 may be anisotropically etched to form a first sacrificial layer pattern 405 and a first spacer 385. Further, a portion of the pad layer pattern 275 exposed during the etching process may be removed, and the active region 220 may be partially exposed.

The first spacer 385 may be formed directly on sidewalls of the bit line contact 325 and the bit line structure 370. The first spacer 385 may extend in the second direction, and a plurality of the first spacers 385 may be formed along the first direction. The first spacer 385 may extend on the pad layer pattern 275 and the inner wall of the recess 310.

The first sacrificial layer pattern 405 may be formed on the first spacer 385 to surround the sidewall of the bit line contact 325 and the bit line structure 370. The first sacrificial layer pattern 405 may extend in the second direction, and a plurality of the first sacrificial layer patterns 405 may be formed along the first direction. The first sacrificial layer pattern 405 may fill a remaining portion of the recess 310.

The first spacer 385 and the first sacrificial layer pattern 405 may be formed by substantially the same etching process or may be independently formed by individual etching processes.

A second sacrificial layer 410 may be formed on the substrate 200 to cover the first sacrificial layer pattern 405 and the bit line structure 370. The second sacrificial layer 410 may be formed using a material that may have an etching selectivity with respect to the first sacrificial layer pattern 405 and the first spacer 385. For example, the second sacrificial layer 410 may be formed using a carbon-based material.

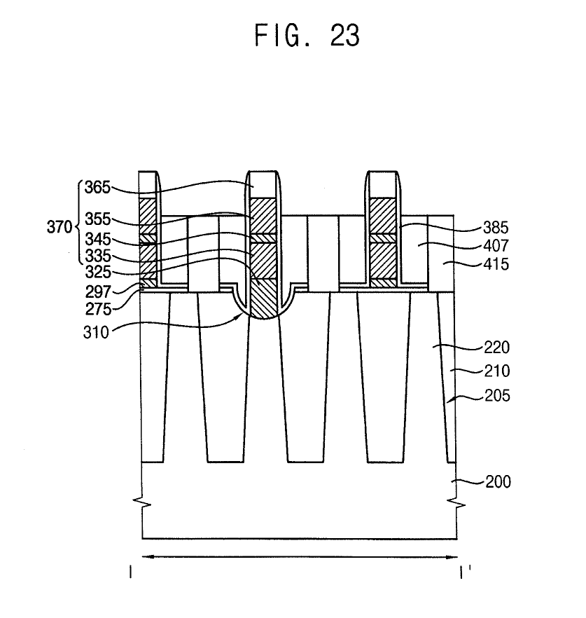

Referring to FIG. 23, upper portions of the second sacrificial layer 410 and the first sacrificial layer pattern 405 may be removed to form a second sacrificial layer pattern 415. The first sacrificial layer pattern 405 may be changed into a third sacrificial layer pattern 407. The third sacrificial layer pattern 407 may be cover on a lower portion of the first spacer 385. The second sacrificial layer pattern 415 may be formed on the isolation layer pattern 210 and the active region 220 to be in contact with sidewalls of the third sacrificial layer pattern 407, the first spacer 385 and the pad layer pattern 275. An upper portion of the first spacer 385 and a top surface of the third mask 365 may be exposed.

In example embodiments, the second sacrificial layer pattern 415 and the third sacrificial layer pattern 407 may be simultaneously formed by a CMP process and/or an etch-back process. A top surface of the third sacrificial layer pattern 407 may be coplanar with a top surface of the second sacrificial layer pattern 415.

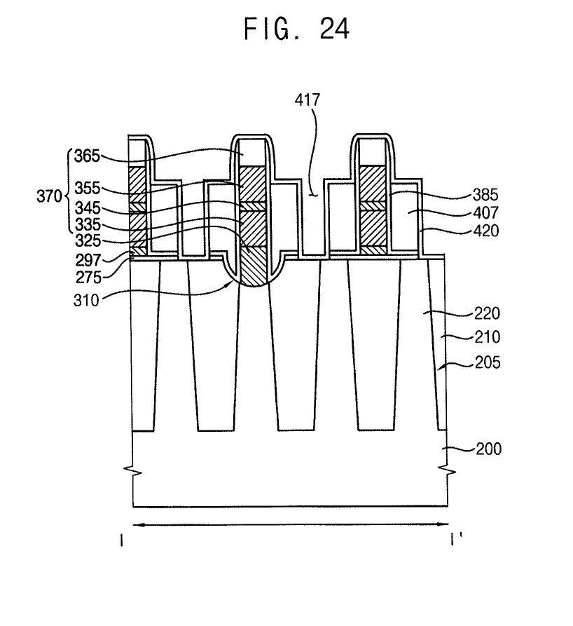

Referring to FIG. 24, the second sacrificial layer pattern 415 may be selectively removed to form a first opening 417 through which the top surface of the active region 220 may be exposed. A second spacer layer 420 may be formed on an inner wall of the first opening 417 and on the third sacrificial layer pattern 407, the first spacer 385 and the bit line structure 370.

In example embodiments, the second sacrificial layer pattern 415 may be removed by a reactive ion etching (RIE) process or a plasma etching process. While performing the etching process, the bit line contact 325, the third conductive layer pattern 335, the barrier layer pattern 345 and the metal layer pattern 355 may be covered by the first spacer 385, and may not be damaged or etched.

The second spacer layer 420 may be formed using a material substantially the same as or similar to that of the first spacer 385, e.g., silicon nitride. The second spacer layer 420 may be merged or integral with the first spacer 385. The second spacer layer 420 may be conformably formed to have a uniform thickness.

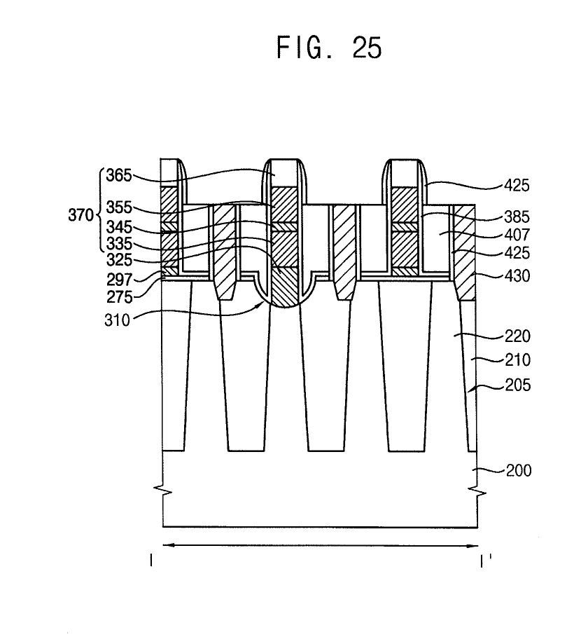

Referring to FIG. 25, the second spacer layer 420 may be anistropically etched to form a second spacer 425. The second spacer 425 may be formed on a sidewall of the first opening 417 and on an upper portion of the first spacer 385. For example, the second spacer 425 may be in contact with sidewalls of the third sacrificial layer pattern 407, the first spacer 385 and the pad layer pattern 275. Top surfaces of the active region 220, the third sacrificial layer pattern 407 and the third mask 365 may be exposed by the etching process.

Further, a portion of the active region 220 exposed by the etching process above may be partially removed to form a second opening extended from the first opening 417. A lower capacitor contact 430 filling the second opening may be formed.

An upper portion of the isolation layer pattern 210 may be also removed while forming the second opening. An upper portion of the active region 220 may be partially exposed.

A fourth conductive layer sufficiently filling the second opening may be formed. An upper portion of the fourth conductive layer may be planarized by a CMP or an etch-back process until the top surface of the third sacrificial layer pattern 407 is exposed to form the lower capacitor contact 430. The lower capacitor contact 430 may at least partially contact the active region 220. A sidewall of the lower capacitor contact 430 may be surrounded by the second spacer 425. The fourth conductive layer may be formed using doped polysilicon or a metal.

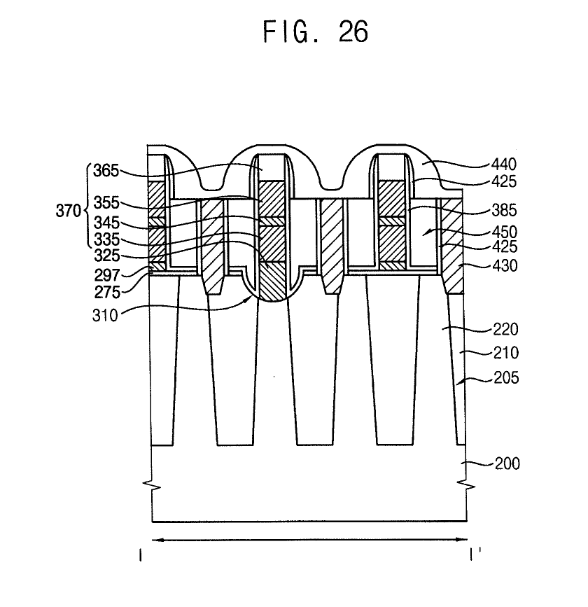

Referring to FIG. 26, the third sacrificial layer pattern 407 may be removed, and then a third spacer layer 440 may be formed on the third mask 365, the second spacer 425 and the lower capacitor contact 430. In example embodiments, an air gap 450 may be defined by the first spacer 385, the second spacer 425 and the third spacer layer 440.

In example embodiments, the third sacrificial layer pattern 407 may be removed by a wet etching process using an etchant solution. The etchant solution may include a hydrofluoric acid solution, a buffer oxide etchant (BOE) solution and/or a low ammonium fluoride liquid (LAL) solution. During the wet etching process, the bit line structure 370 and the bit line contact 325 may be protected by the first spacer 385 and the third mask 365. After the removal of the third sacrificial layer pattern 407, a third opening may be formed to partially expose the first and second spacers 385 and 425.

The third spacer layer 440 may be formed using a material that may have low step-coverage and gap-fill properties. Accordingly, the third spacer layer 440 may be overhang by the second spacer 425 and the low capacitor contact 430, and may not extend into the third opening. At least a portion of the third opening may remain as the air gap 350.

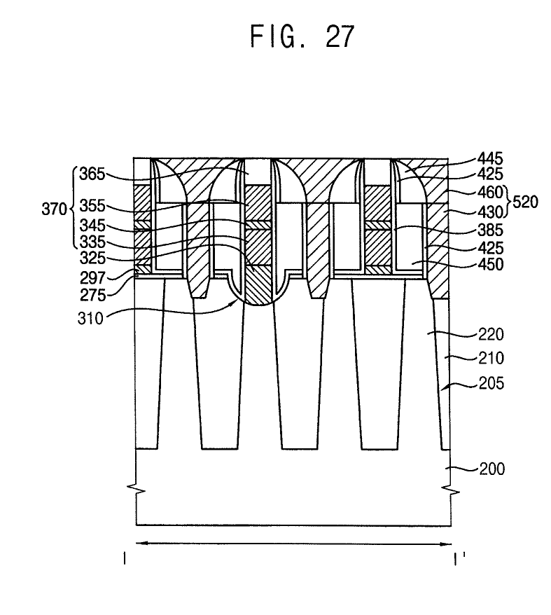

Referring to FIG. 27, the third spacer layer may be anisotropically etched to form a third spacer 445. The third spacer 445 may be formed on the second spacer 425 to cap or close the air gap 350. In one example embodiment, the third spacer 445 may be formed on a portion of a top surface of the lower capacitor contact 430. A fourth opening through which the top surface of the lower capacitor contact 430 is exposed may be formed between the neighboring third spacers 445.

An upper capacitor contact 460 may be formed on the lower capacitor contact 430 to fill the fourth opening. For example, a fifth conductive layer sufficiently filling the fourth opening. An upper portion of the fifth conductive layer may be planarized until the top surface of the third mask 365 is exposed to form the upper capacitor contact 460. The upper capacitor contact 460 may be in direct contact with the lower capacitor contact 430, and may be sandwiched by the neighboring third spacers 445.

The fifth conductive layer may be formed using a material substantially the same as or similar to that of the lower capacitor contact 430. The upper capacitor contact 460 may include dope polysilicon or a metal.

A capacitor contact structure 520 may be defined by the lower capacitor contact 430 and the upper capacitor contact 460.

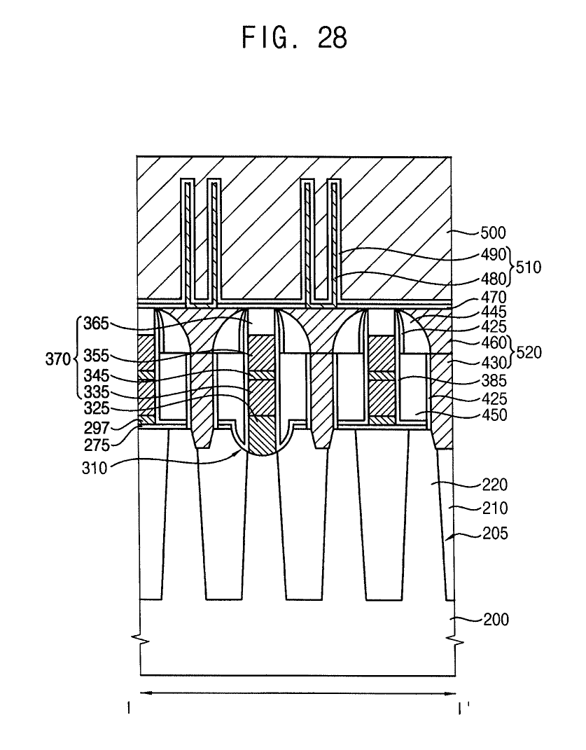

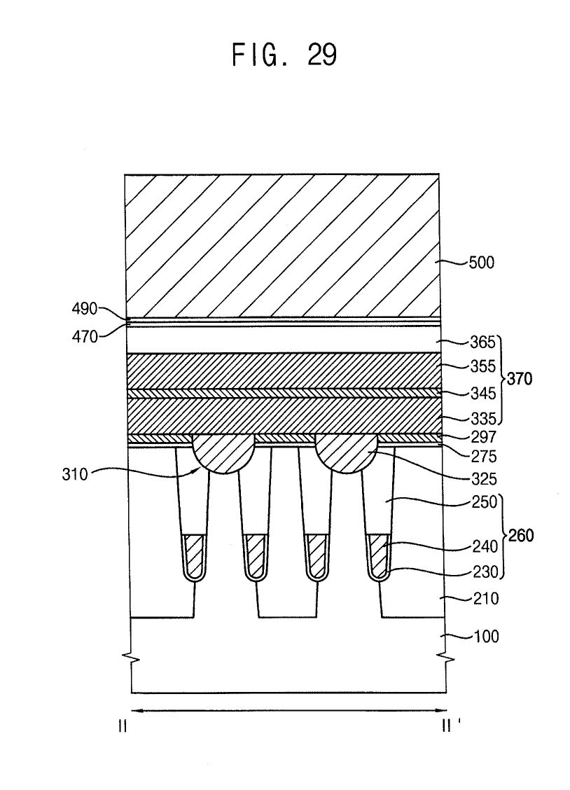

Referring to FIGS. 28 and 29, a capacitor 510 may be formed on the capacitor contact structure 520. The capacitor 510 may be in contact with or electrically connected to the upper capacitor contact 460.

For example, an etch-stop layer 470 and a mold layer (not illustrated) may be formed on the upper capacitor contact 460 and the third mask 365. The etch-stop layer 470 and the mold layer may be partially removed to form a contact hole (not illustrated) through which a top surface of the upper capacitor contact 460 is exposed.

A lower electrode layer may be formed on an inner wall of the contact hole and on the mold layer, and a third sacrificial layer sufficiently filling the contact hole may be formed on the lower electrode layer. Upper portions of the third sacrificial layer and the lower electrode layer may be planarized until a top surface of the mold layer is exposed to form a lower electrode 480 contacting the upper capacitor contact 460. The third sacrificial layer and the mold layer may be removed by a wet etching process. The lower electrode 480 may have a hollow cylindrical shape or a cup shape.

A dielectric layer 490 may be formed on the lower electrode 480 and the etch-stop layer 470, and an upper electrode 500 may be formed on the dielectric layer 490. Accordingly, a capacitor 510 including the lower electrode 480, the dielectric layer 490 and the upper electrode 500 may be obtained.

For example, the lower electrode 480 and the upper electrode 500 may include doped polysilicon, a metal or a metal nitride. The dielectric layer 490 may include, e.g., silicon oxide or a metal oxide such as hafnium oxide, zirconium oxide, titanium oxide, or aluminum oxide.

According to example embodiments, a photoresist pattern may be formed using the photoresist composition that may have improved resolution and adhesion. Various patterns included in the semiconductor device may be formed using the photoresist pattern as an etching mask.

By way of summation and review, as a degree of integration of a semiconductor device becomes increased, a critical dimension or a pitch of the pattern may be decreased, a photoresist composition that may have improved resolution may be needed, and a photolithography process may have improved resolution and sensitivity. In a photolithography process, a photoresist pattern may be formed on an object layer and the object layer may be etched using the photoresist pattern as an etching mask. The photoresist pattern may be separated or detached from the object layer, and the resolution and sensitivity of the photolithography process may be deteriorated. A photoresist composition may include a polymer resin that may have a lactone group as a repeating unit, and adhesion between the photoresist pattern and the object layer may be improved.

Example embodiments provide a photoresist composition that may have improved resolution, and a method of forming a pattern using the photoresist composition.

According to example embodiments, a photoresist composition may include a photosensitive copolymer having a repeating unit from a vinyl sulfone monomer. A sulfone group of the vinyl sulfone monomer may be hydrophilic and may be capable of forming a hydrogen bond. A photoresist pattern formed from the photoresist composition may have improved adhesion, and the photoresist pattern may not be detached or separated from an object layer. The photoresist composition may have improved resolution, and a desired pattern of a semiconductor device, e.g., a pattern that may have a high aspect ratio, may be formed using the photoresist composition.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoresist composition, comprising:
a photosensitive copolymer including a repeating unit from a vinyl sulfone monomer; and
a solvent.

2. The photoresist composition as claimed in claim 1, wherein the photosensitive copolymer is represented by Chemical Formula 1: 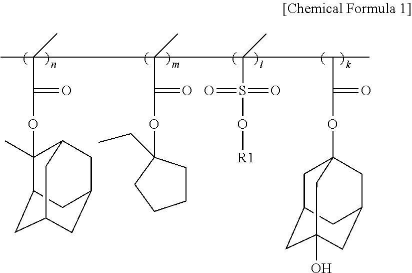
wherein, in Chemical Formula 1, R1 is a hydrocarbon group, and
n, m, l and k are positive integers.

3. The photoresist composition as claimed in claim 1, wherein the photosensitive copolymer is represented by Chemical Formula 2: 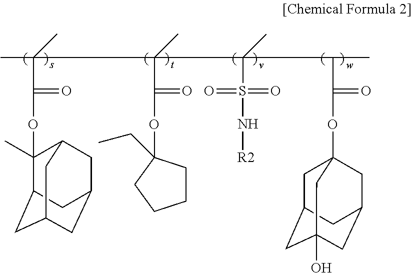
wherein, in Chemical Formula 2, R2 is a hydrocarbon group, and
s, t, v and w are positive integers.

4. The photoresist composition as claimed in claim 1, wherein an amount of the photosensitive copolymer ranges from about 1 weight percent to about 60 weight percent, based on a total weight of the photoresist composition.

5. The photoresist composition as claimed in claim 1, further comprising a photoacid generator and a basic additive.

6. The photoresist composition as claimed in claim 5, wherein an amount of the photoacid generator ranges from about 1 weight percent to about 20 weight percent, based on a total weight of the photoresist composition.

7. The photoresist composition as claimed in claim 5, wherein an amount of the basic additive ranges from about 0.001 weight percent to about 5 weight percent, based on a total weight of the photoresist composition.

8. A method of forming a pattern, comprising:
forming a photoresist layer from a photoresist composition including a photosensitive copolymer and a solvent on an object layer, the photosensitive copolymer including a repeating unit from a vinyl sulfone monomer;
forming a photoresist pattern, forming the photoresist pattern including performing a light exposure on the photoresist layer; and
etching the object layer using the photoresist pattern as an etching mask.

9. The method as claimed in claim 8, wherein the photoresist composition further includes a photoacid generator and a basic additive.

10. The method as claimed in claim 8, wherein the photosensitive copolymer is represented by Chemical Formula 1 or Chemical Formula 2: 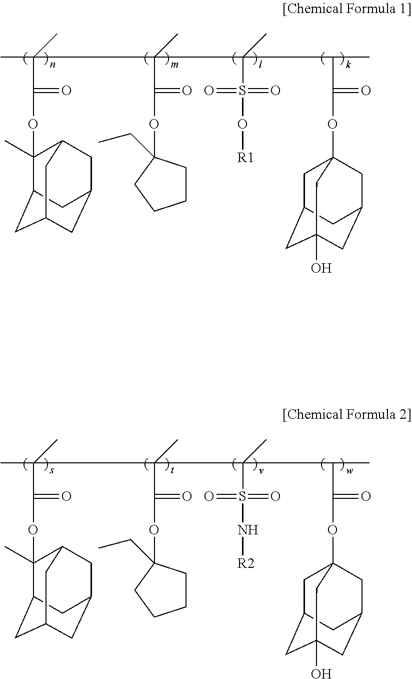
wherein, in Chemical Formula 1 and Chemical Formula 2, R1 and R2 are independently a hydrocarbon group, and
n, m, l, k, s, t, v and w are positive integers.

11. The method as claimed in claim 8, wherein an amount of the photosensitive copolymer ranges from about 1 weight percent to about 60 weight percent, based on a total weight of the photoresist composition.

12. The method as claimed in claim 8, wherein the forming of the photoresist pattern includes:
partially exposing the photoresist layer to light using an exposure mask;
performing a thermal treatment on the photoresist layer; and
developing the photoresist layer using an organic solvent.

13. The method as claimed in claim 12, wherein the thermal treatment is performed at a temperature ranging from about 90° C. to about 130° C.

14. The method as claimed in claim 8, further comprising, before forming the photoresist layer, forming a hard mask layer on the object layer.

15. The method as claimed in claim 14, wherein the etching of the object layer includes:
etching the hard mask layer using the photoresist pattern as an etching mask to form a hard mask;
removing the photoresist pattern; and
etching the object layer using the hard mask as an etching mask.

16. A photoresist composition, comprising:
a photosensitive copolymer including a sulfone group; and
a solvent,
wherein the sulfone group is represented by either of Chemical Formula 3 and Chemical Formula 4: 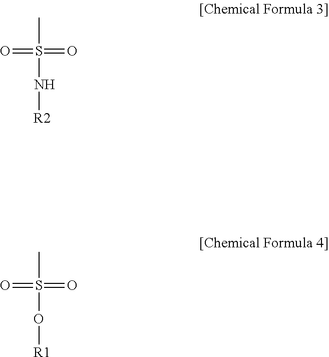
wherein R1 and R2 are independently a hydrocarbon group.

17. The photoresist composition as claimed in claim 16, wherein the photosensitive copolymer includes a plurality of the sulfone group.

18. The photoresist composition as claimed in claim 17, wherein the photosensitive copolymer further includes one or more of the following chemical groups:

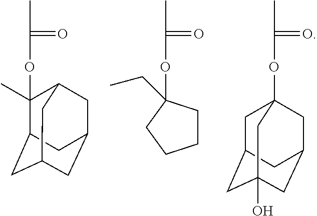

19. The photoresist composition as claimed in claim 18, wherein the photosensitive copolymer includes all the following chemical groups: [chemical structure]
